(19) United States
(12) Patent Application Publication
(10) Pub. No.: US 2022/0197146 A1
(43) Pub. Date: Jun. 23, 2022

(54) PHOTORESISTS BY PHYSICAL VAPOR DEPOSITION

(71) Applicant: Applied Materials, Inc., Santa Clara, CA (US)

(72) Inventors: Lauren Bagby, Palo Alto, CA (US); Stephen Weeks, Santa Clara, CA (US); Aaron Dangerfield, Fremont, CA (US); Lakmal Kalutarage, San Jose, CA (US); Jeffrey Anthis, Campbell, CA (US); Mark Saly, Milpitas, CA (US); Regina Freed, Los Altos, CA (US); Wayne French, San Jose, CA (US); Kelvin Chan, San Ramon, CA (US)

(21) Appl. No.: 17/464,432

(22) Filed: Sep. 1, 2021

Related U.S. Application Data
(60) Provisional application No. 63/129,407, filed on Dec. 22, 2020.

(51) Int. Cl. G03F 7/16

(52) U.S. Cl. CPC G03F 7/167

(57) ABSTRACT

Embodiments include a method of forming a metal oxo photoresist on a substrate. In an embodiment, the method comprises providing a target in a vacuum chamber, where the target comprises a metal. The method may continue with flowing a hydrocarbon gas and an inert gas into the vacuum chamber, and striking a plasma in the vacuum chamber. In an embodiment, the method further continues with depositing the metal oxo photoresist on the substrate, where the metal oxo photoresist comprise metal-carbon bonds and metal-oxygen bonds.

### CROSS-REFERENCE TO RELATED APPLICATIONS

This application claims the benefit of U.S. Provisional Application No. 63/129,407, filed on Dec. 22, 2020, the entire contents of which are hereby incorporated by reference herein.

### BACKGROUND

### 1) Field

Embodiments of the present disclosure pertain to the field of semiconductor processing and, in particular, to methods of depositing a metal oxide photoresist layer onto a substrate using a sputter deposition process.

### 2) Description of Related Art

Lithography has been used in the semiconductor industry for decades for creating 2D and 3D patterns in microelectronic devices. The lithography process involves spin-on deposition of a film (photoresist), irradiation of the film with a selected pattern by an energy source (exposure), and removal (etch) of exposed (positive tone) or non-exposed (negative tone) region of the film by dissolving in a solvent. A bake will be carried out to drive off remaining solvent.

The photoresist should be a radiation sensitive material and upon irradiation a chemical transformation occurs in the exposed part of the film which enables a change in solubility between exposed and non-exposed regions. Using this solubility change, either exposed or non-exposed regions of the photoresist is removed (etched). Now the photoresist is developed and the pattern can be transferred to the underlying thin film or substrate by etching. After the pattern is transferred, the residual photoresist is removed and repeating this process many times can give 2D and 3D structures to be used in microelectronic devices.

Several properties are important in lithography processes. Such important properties include sensitivity, resolution, lower line-edge roughness (LER), etch resistance, and ability to form thinner layers. When the sensitivity is higher, the energy required to change the solubility of the as-deposited film is lower. This enables higher efficiency in the lithographic process. Resolution and LER determine how narrow features can be achieved by the lithographic process. Higher etch resistant materials are required for pattern transferring to form deep structures. Higher etch resistant materials also enable thinner films. Thinner films increase the efficiency of the lithographic process.

### SUMMARY

Embodiments include a method of forming a metal oxo photoresist on a substrate. In an embodiment, the method comprises providing a target in a vacuum chamber, where the target comprises a metal. The method may continue with flowing a hydrocarbon gas and an inert gas into the vacuum chamber, and striking a plasma in the vacuum chamber. In an embodiment, the method further continues with depositing the metal oxo photoresist on the substrate, where the metal oxo photoresist comprise metal-carbon bonds and metal-oxygen bonds.

Additional embodiments include a method of forming a metal oxo photoresist on a substrate. In an embodiment, the method comprises providing a first target in a vacuum chamber, where the first target comprises a metal, and providing a second target in the vacuum chamber, where the second target comprises carbon. In an embodiment, the method further comprises flowing a hydrocarbon gas an inert gas into the vacuum chamber, and striking a plasma in the vacuum chamber. In an embodiment, the method further comprises depositing the metal oxo photoresist on the substrate, where the metal oxo photoresist comprise metal-carbon bonds and metal-oxygen bonds.

In yet another embodiment, a method of depositing a metal oxo photoresist on a substrate is provided. In an embodiment, the method comprises sputtering a first metal oxo layer onto the substrate in a vacuum chamber, where the first metal oxo layer has a first composition. In an embodiment, the method further comprises sputtering a second metal oxo layer onto the first metal oxo layer, where the second metal oxo layer has a second composition that is different than the first composition.

### BRIEF DESCRIPTION OF THE DRAWINGS

FIG. 1 is a process flow diagram illustrating a physical vapor deposition (PVD) process with a metal oxo target, in accordance with an embodiment.

FIG. 2 is a process flow diagram illustrating a PVD process with a metal oxo target and the flow of an oxygen containing source gas and/or a carbon containing source gas, in accordance with an embodiment.

FIG. 3 is a process flow diagram illustrating a PVD process with a plurality of targets with different material compositions.

FIG. 4 is a process flow diagram illustrating a PVD process with a metal target and the flow of a hydrocarbon gas, in accordance with an embodiment.

FIG. 5 is a process flow diagram illustrating a PVD process with a metal target and a carbon target with the flow of a hydrocarbon gas, in accordance with an embodiment.

FIG. 6 is a process flow diagram illustrating a PVD process with a target comprising metal, carbon, and hydrogen, in accordance with an embodiment.

FIG. 7 is a process flow diagram illustrating a PVD process with a metal containing target that comprises hydrogen, in accordance with an embodiment.

FIG. 8A is a process flow diagram illustrating a PVD process for depositing an non-uniform layer over a substrate, in accordance with an embodiment.

FIG. 8B is a cross-sectional illustration of a metal oxo layer over a substrate, where the metal oxo layer comprises a non-uniform material composition, in accordance with an embodiment.

FIG. 8C is a cross-sectional illustration of a metal oxo layer over a substrate, where the metal oxo layer has a compositional gradient through its thickness, in accordance with an embodiment.

FIG. 9A is a cross-sectional illustration of a PVD tool with a metal oxo target, in accordance with an embodiment.

FIG. 9B is a cross-sectional illustration of a PVD tool with a plurality of targets, in accordance with an embodiment.

FIG. 10 illustrates a block diagram of an exemplary computer system, in accordance with an embodiment of the present disclosure.

### DETAILED DESCRIPTION

Methods of depositing a metal oxide photoresist layer onto a substrate using a sputter deposition process are described herein. In the following description, numerous specific details are set forth in order to provide a thorough understanding of embodiments of the present disclosure. It will be apparent to one skilled in the art that embodiments of the present disclosure may be practiced without these specific details. In other instances, well-known aspects, such as integrated circuit fabrication, are not described in detail in order to not unnecessarily obscure embodiments of the present disclosure. Furthermore, it is to be understood that the various embodiments shown in the Figures are illustrative representations and are not necessarily drawn to scale.

To provide context, photoresist systems used in extreme ultraviolet (EUV) lithography suffer from low efficiency. That is, existing photoresist material systems for EUV lithography require high dosages in order to provide the needed solubility switch that allows for developing the photoresist material. Organic-inorganic hybrid materials (e.g., metal oxo materials systems) have been proposed as a material system for EUV lithography due to the increased sensitivity to EUV radiation. Such material systems typically comprise a metal (e.g., Sn, Hf, Zr, etc.), oxygen, and carbon. Metal oxo based organic-inorganic hybrid materials have also been shown to provide lower LER and higher resolution, which are required characteristics for forming narrow features.

Metal oxo material systems are currently disposed over a substrate using a wet process. The metal oxo material system is dissolved in a solvent and distributed over the substrate (e.g., a wafer) using wet chemistry deposition processes, such as a spin coating process. Wet chemistry deposition of the photoresist suffers from several drawbacks. One negative aspect of wet chemistry deposition is that a large amount of wet byproducts are generated. Wet byproducts are not desirable and the semiconductor industry is actively working to reduce wet byproducts wherever possible. Additionally, wet chemistry deposition may result in non-uniformity issues. For example, spin-on deposition may provide a photoresist layer that has a non-uniform thickness or non-uniform distribution of the metal oxo molecules. Additionally, it has been shown that metal oxo photoresist material systems suffer from thickness reduction after exposure, which is troublesome in lithographic processes. Furthermore, in a spin-on process, the percentage of metal in the photoresist is fixed, and cannot be easily tuned.

Accordingly, embodiments of the present disclosure provide a physical vapor deposition (PVD) process, such as a sputtering process, to deposit a metal oxide photoresist layer onto a substrate. The PVD process addresses the shortcomings of the wet deposition process described above. Particularly, a PVD process provides the advantages of: 1) eliminating the generation of wet byproducts; 2) providing a highly uniform photoresist layer; and 3) providing a line of site deposition process that eliminates backside deposition.

Embodiments disclosed herein provide various PVD processes that allow for the dry deposition of a metal oxo photoresist on a substrate. In an embodiment, the target material has a composition that is the desired composition of the metal oxo photoresist. In such embodiments, an inert gas is flown into the chamber and a plasma is struck. The plasma results in the sputtering of the target material onto the substrate. In other embodiments, additional processing gasses may be flown into the chamber during the sputtering process. For example, an oxygen containing source gas and/or a carbon containing source gas may be flown into the chamber during the processing. The additional processing gasses may incorporate into the deposited film to provide a composition different than that of the target material. Additionally, the flow of the additional processing gasses may be modulated throughout the sputtering process to provide a layer with a non-uniform composition through the thickness of the deposited layer. In yet another embodiment, multiple targets may be provided in the chamber. A first target may comprise the metal oxo material and a second target may comprise carbon and/or oxygen. As such, the deposited layer may have a composition different than that of the metal oxo target.

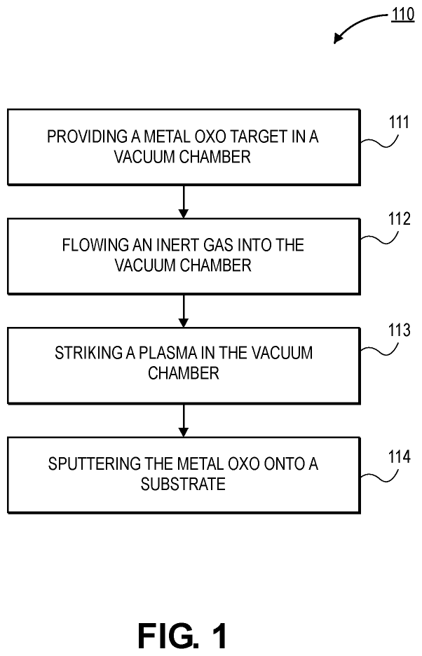

Referring now to FIG. 1, a process flow diagram of a process 110 is shown, in accordance with an embodiment. In an embodiment, process 110 may begin with operation 111, which comprises providing a metal oxo target in a vacuum chamber. The metal oxo target may comprise a metal (e.g., Sn, Hf, Zr, etc.), oxygen, and carbon. In a particular embodiment, the metal oxo target comprises Sn, oxygen, and carbon. The target may be formed with various processing techniques. In one embodiment, a metal oxo powder may be cold pressed to form the target. Additional embodiments may include a sintering process of a metal oxo powder. In yet another embodiment, the metal oxo is solution cast and solidified. In an embodiment the solid metal oxo materials may be attached to a metal plate. While particular examples of methods of forming the metal oxo target are shown, it is to be appreciated that the metal oxo target may be formed with any suitable process.

In an embodiment, process 110 may continue with operation 112 which comprises flowing an inert gas into the vacuum chamber. In a particular embodiment the inert gas comprises argon.

In an embodiment, process 110 may continue with operation 113, which comprises striking a plasma in the vacuum chamber. Since the target is an insulating material, the plasma is struck using an RF or pulsed DC setup. In an embodiment, the plasma may be struck with any suitable pressure. In a particular embodiment, the pressure may be approximately 20 mTorr or lower.

In an embodiment, process 110 may continue with operation 114, which comprises sputtering the metal oxo onto a substrate. In an embodiment, the sputtering operation may continue for a period of time to provide a metal oxo layer on the substrate with a desired thickness. In an embodiment, the metal oxo layer on the substrate may have a composition that is substantially similar to the composition of the metal oxo target. Additionally, it is to be appreciated that a sputtering process will result in the metal oxide layer on the substrate having a high uniformity across the surface of the substrate.

It is to be appreciated that sputtering processes are line of sight deposition processes. As such, the sputtering process will not result is deposition on a backside surface of the substrate. This is particularly beneficial compared to other dry deposition processes (e.g., atomic layer deposition (ALD) or chemical vapor deposition (CVD)) which need to account for the propensity to have backside deposition.

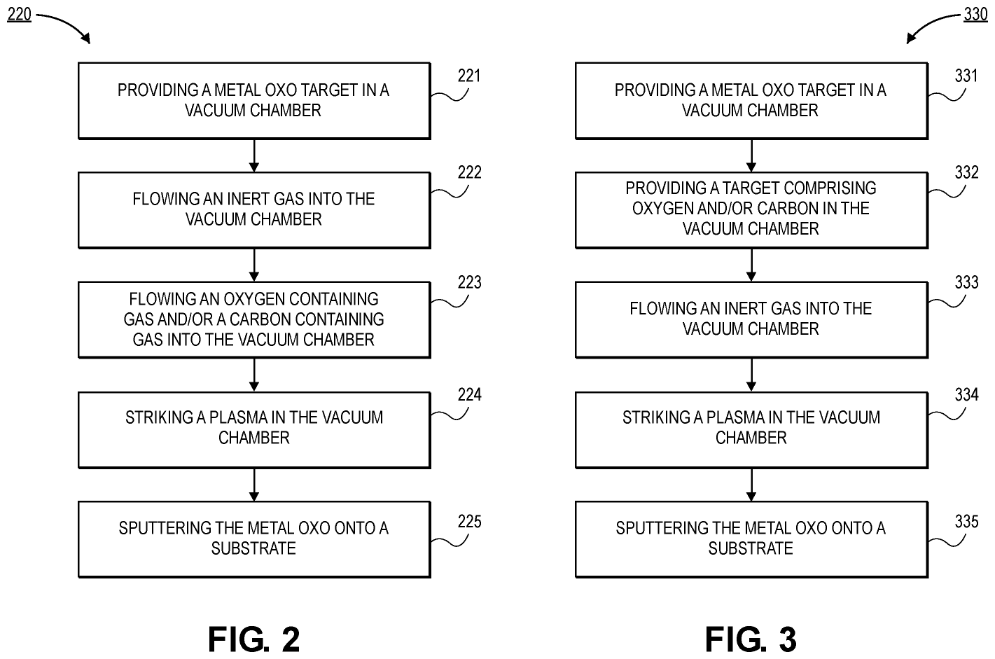

Referring now to FIG. 2, a process flow diagram of a process 220 for depositing a metal oxo layer on a substrate is shown, in accordance with an embodiment. In an embodiment, process 220 may begin with operation 221, which comprises providing a metal oxo target in a vacuum chamber. In an embodiment, the metal oxo target may be substantially similar to the metal oxo target described in process 110. That is, the metal oxo target may be formed with a cold pressing process, a sintering process, a solution casting process, or the like.

In an embodiment, process 220 may continue with operation 222, which comprises flowing an inert gas into the vacuum chamber. In an embodiment, the inert gas may comprise argon or the like. In an embodiment, process 220 may continue with operation 223, which comprises flowing an oxygen containing gas and/or a carbon containing gas into the vacuum chamber. The flow of oxygen and/or carbon containing gasses may be used to modify the amount of oxygen and/or carbon that is incorporated into the metal oxo layer on the substrate. It is to be appreciated that the inert gas and the oxygen and/or carbon containing source gasses may be flown into the chamber at the same time. Additionally, the reactive sputtering process with the flow of oxygen and/or carbon containing gasses may allow for the target to be a metal instead of a metal oxo material. That is, the oxygen and carbon of the deposited metal oxo film may be sourced from the oxygen and/or carbon containing gasses instead of (or in addition to) oxygen and carbon in the target material.

In an embodiment, process 220 may continue with operation 224, which comprises striking a plasma in the vacuum chamber. Since the target is an insulating material, the plasma is struck using an RF or pulsed DC setup. In an embodiment, the plasma may be struck with any suitable pressure. In a particular embodiment, the pressure may be approximately 20 mTorr or lower.

In an embodiment, process 220 may continue with operation 225, which comprises sputtering the metal oxo onto a substrate. In an embodiment, the sputtering operation may continue for a period of time to provide a metal oxo layer on the substrate with a desired thickness. Due to the flow of an oxygen containing source gas and/or a carbon containing source gas, the metal oxo layer on the substrate may have a composition that is different than the composition of the metal oxo target. Additionally, it is to be appreciated that, by changing the flowrate of the oxygen containing source gas and/or the carbon containing source gas, the composition of the metal oxo layer may be non-uniform through a thickness of the metal oxo layer. For example, a composition of the metal oxo layer may be tuned to provide improved adhesion at the interface with the substrate and have improved sensitivity through the remainder of the thickness of the metal oxo layer.

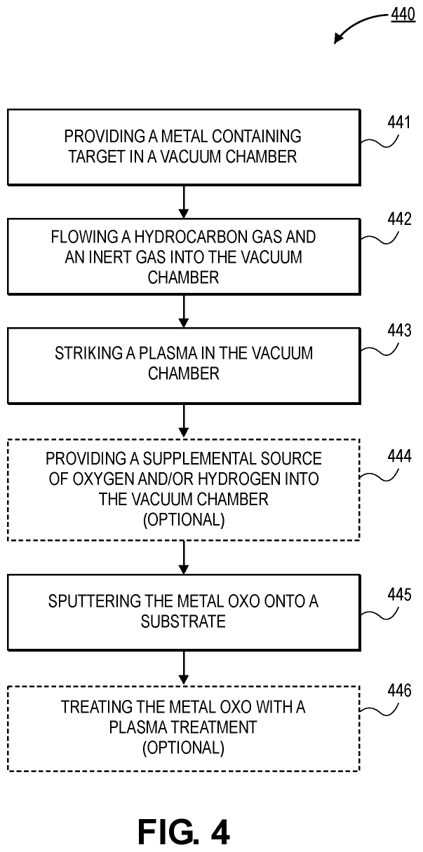

Referring now to FIG. 3, a process flow diagram of a process 330 for depositing a metal oxo layer on a substrate is shown, in accordance with an embodiment. In an embodiment, process 330 may begin with operation 331, which comprises providing a metal oxo target in a vacuum chamber. In an embodiment, the metal oxo target may be substantially similar to the metal oxo target described in process 110. That is, the metal oxo target may be formed with a cold pressing process, a sintering process, a solution casting process, or the like.

Process 330 may continue with operation 332, which comprises providing a target comprising oxygen and/or carbon in the vacuum chamber. That is, a multi-cathode chamber design may be provided. As such, the deposited material composition can be different than the composition of the metal oxo target.

Process 330 may continue with operation 333, which comprises flowing an inert gas into the vacuum chamber. In an embodiment, the inert gas comprises argon or the like. In some embodiments, a carbon containing gas and/or an oxygen containing gas may also be flown into the chamber, similar to process 220.

Process 330 may continue operation 334, which comprises striking a plasma in the vacuum chamber. Since the target is an insulating material, the plasma is struck using an RF or pulsed DC setup. In an embodiment, the plasma may be struck with any suitable pressure. In a particular embodiment, the pressure may be approximately 20 mTorr or lower.

Process 330 may continue with operation 334, which comprises sputtering the metal oxo onto a substrate. In an embodiment, the sputtering operation may continue for a period of time to provide a metal oxo layer on the substrate with a desired thickness. In an embodiment, the multi-cathode setup results in the metal oxo layer on the substrate having a composition that is different than the composition of the metal oxo target. Additionally, it is to be appreciated that a sputtering process will result in the metal oxide layer on the substrate having a high uniformity across the surface of the substrate.

In process 330, a plurality of targets are used in order to provide the metal oxo film on the substrate. It is to be appreciated that the material compositions of the various targets may be any compositions that can be used to form the metal oxo film. For example, a first target may comprise a metal and a second target may comprise an oxide. Such setups may further include reactive sputtering that includes the flow of an oxygen containing gas and/or a carbon containing gas during the sputtering operation. Additionally, more than two targets may be used. For example, a carbon containing target may also be included in addition to the metal target and the oxide target.

In the embodiments described above, the target comprises a metal oxo material. That is, the target comprises a metal, oxygen, and carbon. However, in additional embodiments, the target may comprise only the metal. The additional elements (e.g., oxygen and carbon) incorporated into the metal oxo photoresist are provided by a reactive sputtering process. That is, additional gasses comprising oxygen and carbon are flown into the vacuum chamber in order to react with the metal to form the metal oxo photoresist. Embodiments that use such reactive sputtering processes are described in greater detail below.

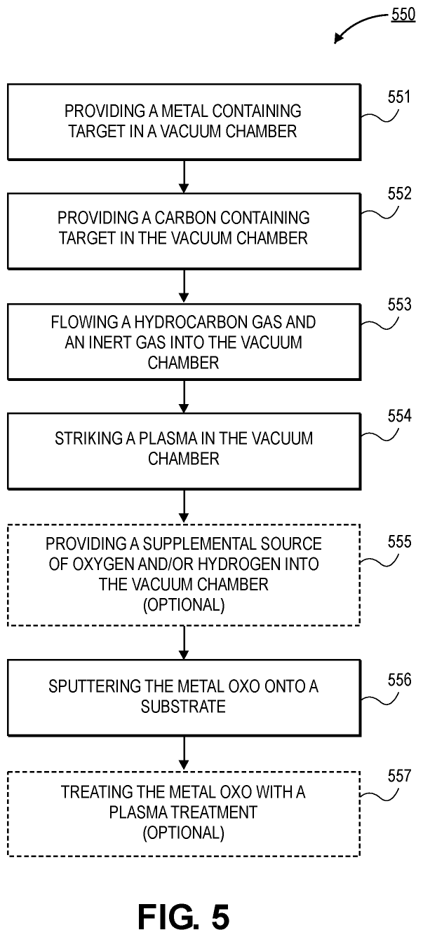

Referring now to FIG. 4, a flow diagram of a process 440 for depositing a metal oxo photoresist on a substrate is shown, in accordance with an embodiment. In an embodiment, the process 440 may begin with operation 441, which comprises providing a metal containing target in a vacuum chamber. In an embodiment, the metal may be any suitable metal for forming a metal oxo photoresist. In one embodiment, the metal is Sn. However, embodiments may also include metals such as, but not limited to, Sn, In, Hf, Zr, Co, Cr, Mn, Fe, Cu, Ni, Mo, W, Os, Re, Pd, Pt, Ti, V, Al, Sb, Bi, Te, As, Ge, Se, Cd, Ag, Pb, Su, Er, Yb, Pr, La, Na, Mg, and alloys thereof.

In an embodiment, process 440 may continue with operation 442, which comprises flowing a hydrocarbon gas and an inert gas into the vacuum chamber. In an embodiment, the total gas flow may be approximately 50% or less hydrocarbon gas and approximately 50% or more inert gas. In other embodiments, the total gas flow may be approximately 10% or less hydrocarbon gas and approximately 90% or more inert gas. In yet another embodiment, the total gas flow may be approximately 5% or less hydrocarbon gas and approximately 95% or more inert gas.

In an embodiment, the inert gas may comprise Ar. Though, it is to be appreciated that other inert gasses may be used or blends of multiple different inert gases may be used. In an embodiment, the hydrocarbon gas may be any suitable hydrocarbon. For example, the hydrocarbon gas may comprise methane (CH₄) blends, ethane (C₂H₆) blends, propane (C₃H₈) blends, iso- and normal butane (C₄H₁₀) blends, and iso- and normal pentane (C₅H₁₂) blends. It is to be appreciated that the presence of hydrogen in the gas flow may be responsible for opening up reaction pathways during deposition that may increase the reaction between the metal and the carbon.

In an embodiment, the process 440 may continue with operation 443, which comprises striking a plasma in the vacuum chamber. In an embodiment, the plasma may be struck during the flowing of the hydrocarbon gas and the inert gas. That is, operation 442 and 443 may be implemented substantially in parallel with each other. In other embodiments, operation 443 may be implemented before operation 442. In an embodiment, the plasma is struck using an RF or pulsed DC setup. In an embodiment, the plasma may be struck with any suitable pressure. In a particular embodiment, the pressure may be approximately 20 mTorr or lower. While examples of various plasma settings are provided herein, it is to be appreciated that a large range of plasma settings and electrical setups may be used to implement operation 443.

In an embodiment, the process 440 may continue with optional operation 444, which comprises providing a supplemental source of oxygen and/or hydrogen into the vacuum chamber. In an embodiment, the additional flow of oxygen may allow for an increased percentage of metal-oxygen bonds in the metal oxo photoresist. Additionally, the excess flow of hydrogen improves reaction pathways, as described in greater detail above. In an embodiment, hydrogen and oxygen sources may comprise, but are not limited to, O₂, H₂, aldehydes, CO₂, CO, H₂O, N₂O, NO₂, and H₂O₂.

In an embodiment, the process 440 may continue with operation 445, which comprises sputtering the metal oxo onto a substrate in the vacuum chamber. In an embodiment, In an embodiment, the ionized gas bombards the surface of the metal target and reacts to form bonds including, but not limited to, metal-carbon bonds, metal-oxygen bonds, and their hydrides. The resulting material is then deposited on the substrate to form the metal oxo photoresist.

In an embodiment, the process 440 may continue with optional operation 446, which comprises treating the metal oxo photoresist with a plasma treatment. In an embodiment, the plasma treatment may include a plasma comprising, but not limited to, carbon, hydrogen, and oxygen. Source gasses may include, but are not limited to, O₂, H₂, hydrocarbons, aldehydes, CO₂, CO, H₂O, and H₂O₂.

In an embodiment, the metal oxo photoresist may be exposed (e.g., with DUV or EUV radiation). The exposed metal oxo photoresist may then be developed. The developing chemistry may be any suitable developer chemistry. In an embodiment, inorganic bases can be prepared in water, and the concentration and develop time can be adjusted depending on the needs of the metal oxo photoresist. In an embodiment, the developer chemistry may include group 1 and/or group 2 hydroxides (e.g., NH₄OH, NaHCO₃, NaCO₃, N(CH₃)₄OH, amines, and the like). Organic solvents may include 2-heptanone, IPA, octanone, toluene, hexane, and other organic solvents. In a particular embodiment, a 0.05M NaOH developer may be used.

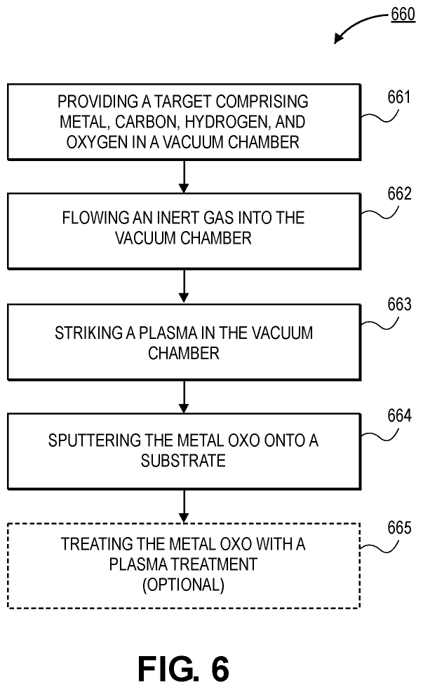

Referring now to FIG. 5, a flow diagram of a process 550 for depositing a metal oxo photoresist on a substrate in a vacuum chamber is shown, in accordance with an embodiment. In an embodiment, the process 550 may begin with operation 551, which comprises providing a metal containing target in a vacuum chamber. In an embodiment, the metal may be any suitable metal for forming a metal oxo photoresist. In one embodiment, the metal is Sn. However, embodiments may also include metals such as, but not limited to, Sn, In, Hf, Zr, Co, Cr, Mn, Fe, Cu, Ni, Mo, W, Os, Re, Pd, Pt, Ti, V, Al, Sb, Bi, Te, As, Ge, Se, Cd, Ag, Pb, Su, Er, Yb, Pr, La, Na, Mg, and alloys thereof.

In an embodiment, the process 550 may continue with operation 552, which comprises providing a carbon containing target in the vacuum chamber. In an embodiment, the carbon containing target may further comprise hydrogen. That is, embodiments may include a multi-target sputtering system. The two targets provide the metal and the carbon used to form the metal oxo photoresist.

In an embodiment, the process 550 may continue with operation 553 which comprises flowing a hydrocarbon gas and an inert gas into the vacuum chamber. In an embodiment, the total gas flow may be approximately 50% or less hydrocarbon gas and approximately 50% or more inert gas. In other embodiments, the total gas flow may be approximately 10% or less hydrocarbon gas and approximately 90% or more inert gas. In yet another embodiment, the total gas flow may be approximately 5% or less hydrocarbon gas and approximately 95% or more inert gas.

In an embodiment, the inert gas may comprise Ar. Though, it is to be appreciated that other inert gasses may be used or blends of multiple different inert gases may be used. In an embodiment, the hydrocarbon gas may be any suitable hydrocarbon. For example, the hydrocarbon gas may comprise methane (CH₄) blends, ethane (C₂H₆) blends, propane (C₃H₈) blends, iso- and normal butane (C₄H₁₀) blends, and iso- and normal pentane (C₅H₁₂) blends. It is to be appreciated that the presence of hydrogen in the gas flow may be responsible for opening up reaction pathways during deposition that may increase the reaction between the metal and the carbon.

In an embodiment, the process 550 may continue with operation 554 which comprises striking a plasma in the vacuum chamber. In an embodiment, the plasma may be struck during the flowing of the hydrocarbon gas and the inert gas. That is, operation 553 and 554 may be implemented substantially in parallel with each other. In an embodiment, the plasma is struck using an RF or pulsed DC setup. In an embodiment, the plasma may be struck with any suitable pressure. In a particular embodiment, the pressure may be approximately 20 mTorr or lower. While examples of various plasma settings are provided herein, it is to be appreciated that a large range of plasma settings and electrical setups may be used to implement operation 554.

In an embodiment, the process 550 may continue with optional operation 555, which comprises providing a supplemental source of oxygen and/or hydrogen into the vacuum chamber. In an embodiment, the additional flow of oxygen may allow for an increased percentage of metal-oxygen bonds in the metal oxo photoresist. Additionally, the excess flow of hydrogen improves reaction pathways, as described in greater detail above. In an embodiment, hydrogen and oxygen sources may comprise, but are not limited to, O₂, H₂, aldehydes, CO₂, CO, H₂O, N₂O, NO₂, and H₂O₂.

In an embodiment, the process 550 may continue with operation 556, which comprises sputtering the metal oxo onto a substrate in the vacuum chamber. In an embodiment, the ionized gas bombards the surface of the metal target and the carbon target and drives reactions to form bonds including, but not limited to, metal-carbon bonds, metal-oxygen bonds, and their hydrides. The resulting material is then deposited on the substrate to form the metal oxo photoresist.

In an embodiment, the process 550 may continue with optional operation 557, which comprises treating the metal oxo photoresist with a plasma treatment. In an embodiment, the plasma treatment may include a plasma comprising, but not limited to, carbon, hydrogen, and oxygen. Source gasses may include, but are not limited to, O₂, H₂, hydrocarbons, aldehydes, CO₂, CO, H₂O, and H₂O₂.

In an embodiment, the metal oxo photoresist may be exposed and developed. The exposure and the developer chemistry may be substantially similar to the developer chemistry described above with respect to process 440. In a particular embodiment, a 0.05M NaOH developer may be used.

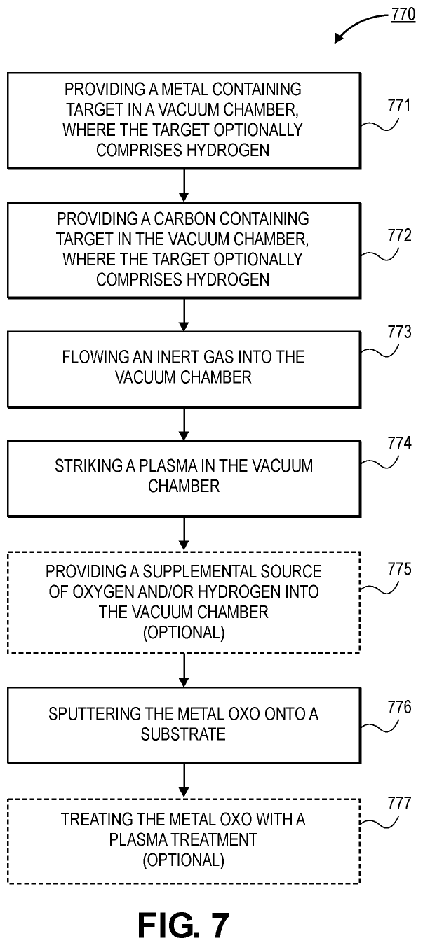

Referring now to FIG. 6, a flow diagram of a process 660 for depositing a metal oxo photoresist on a substrate in a vacuum chamber is shown, in accordance with an embodiment. In an embodiment, the process 660 may begin with operation 661, which comprises providing a target comprising metal, carbon, hydrogen, and oxygen in a vacuum chamber. In an embodiment, the material composition of the target may be the desired composition of the metal oxo photoresist that will be deposited on the substrate. The target may be formed with various processing techniques. In one embodiment, a metal oxo powder may be cold pressed to form the target. Additional embodiments may include a sintering process of a metal oxo powder to form the target. In yet another embodiment, the metal oxo target is solution cast and solidified. In one embodiment, the metal is Sn. However, embodiments may also include metals such as, but not limited to, Sn, In, Hf, Zr, Co, Cr, Mn, Fe, Cu, Ni, Mo, W, Os, Re, Pd, Pt, Ti, V, Al, Sb, Bi, Te, As, Ge, Se, Cd, Ag, Pb, Su, Er, Yb, Pr, La, Na, Mg, and alloys thereof.

In an embodiment, process 660 may continue with operation 662, which comprises flowing an inert gas into the vacuum chamber. In an embodiment, the inert gas comprises Ar. However, it is to be appreciated that other inert gasses may be used as well.

In an embodiment, process 660 may continue with operation 663, which comprises striking a plasma in the vacuum chamber. In an embodiment, the plasma may be struck during the flowing of the inert gas. That is, operation 662 and 663 may be implemented substantially in parallel with each other. In an embodiment, the plasma is struck using an RF or pulsed DC setup. In an embodiment, the plasma may be struck with any suitable pressure. In a particular embodiment, the pressure may be approximately 20 mTorr or lower. While examples of various plasma settings are provided herein, it is to be appreciated that a large range of plasma settings and electrical setups may be used to implement operation 663.

In an embodiment, process 660 may continue with operation 664, which comprises sputtering the metal oxo onto a substrate in the vacuum chamber. In an embodiment, the ionized gas bombards the surface of the metal oxo target, and the material is then deposited on the substrate to form the metal oxo photoresist.

In an embodiment, the process 660 may continue with optional operation 665, which comprises treating the metal oxo photoresist with a plasma treatment. In an embodiment, the plasma treatment may include a plasma comprising, but not limited to, carbon, hydrogen, and oxygen. Source gasses may include, but are not limited to, O₂, H₂, hydrocarbons, aldehydes, CO₂, CO, H₂O, and H₂O₂.

In an embodiment, the metal oxo photoresist may be exposed and developed. The exposure and the developer chemistry may be substantially similar to the developer chemistry described above with respect to process 440. In a particular embodiment, a 0.05M NaOH developer may be used.

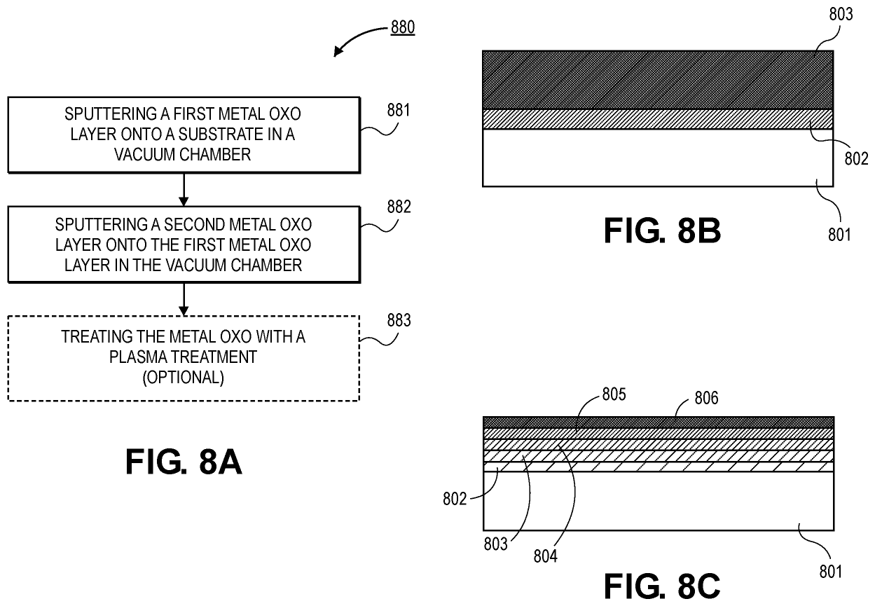

Referring now to FIG. 7, a flow diagram of a process 770 for depositing a metal oxo photoresist on a substrate in a vacuum chamber is shown, in accordance with an embodiment. In an embodiment, the process 770 may begin with operation 771, which comprises providing a metal containing target in a vacuum chamber. In an embodiment, the metal may be any suitable metal for forming a metal oxo photoresist. In one embodiment, the metal is Sn. However, embodiments may also include metals such as, but not limited to, Sn, In, Hf, Zr, Co, Cr, Mn, Fe, Cu, Ni, Mo, W, Os, Re, Pd, Pt, Ti, V, Al, Sb, Bi, Te, As, Ge, Se, Cd, Ag, Pb, Su, Er, Yb, Pr, La, Na, Mg, and alloys thereof. In some embodiments, the target may optionally comprise hydrogen in addition to the metal.

In an embodiment, the process 770 may continue with operation 772, which comprises providing a carbon containing target in the vacuum chamber. In an embodiment, the carbon containing target may further comprise hydrogen. In an embodiment, the carbon target may optionally comprise hydrogen. That is, embodiments may include a multi-target sputtering system. The two targets provide the metal and the carbon used to form the metal oxo photoresist.

In an embodiment, the process 770 may continue with operation 773 which comprises flowing an inert gas into the vacuum chamber. In an embodiment, the inert gas may comprise Ar. Though, it is to be appreciated that other inert gasses may be used or blends of multiple different inert gases may be used. It is to be appreciated that the presence of hydrogen in one or both of the metal target and the carbon target may be responsible for opening up reaction pathways during deposition that may increase the reaction between the metal and the carbon.

In an embodiment, the process 770 may continue with operation 7744 which comprises striking a plasma in the vacuum chamber. In an embodiment, the plasma may be struck during the flowing of the inert gas. That is, operation 773 and 774 may be implemented substantially in parallel with each other. In an embodiment, the plasma is struck using an RF or pulsed DC setup. In an embodiment, the plasma may be struck with any suitable pressure. In a particular embodiment, the pressure may be approximately 20 mTorr or lower. While examples of various plasma settings are provided herein, it is to be appreciated that a large range of plasma settings and electrical setups may be used to implement operation 774.

In an embodiment, the process 770 may continue with optional operation 775, which comprises providing a supplemental source of oxygen and/or hydrogen into the vacuum chamber. In an embodiment, the additional flow of oxygen may allow for an increased percentage of metal-oxygen bonds in the metal oxo photoresist. Additionally, the excess flow of hydrogen improves reaction pathways, as described in greater detail above. In an embodiment, hydrogen and oxygen sources may comprise, but are not limited to, O₂, H₂, aldehydes, CO₂, CO, H₂O, N₂O, NO₂, and H₂O₂.

In an embodiment, the process 770 may continue with operation 776, which comprises sputtering the metal oxo onto a substrate in the vacuum chamber. In an embodiment, the ionized gas bombards the surface of the metal target and the carbon target and drives reactions to form bonds including, but not limited to, metal-carbon bonds, metal-oxygen bonds, and their hydrides. The resulting material is then deposited on the substrate to form the metal oxo photoresist.

In an embodiment, the process 770 may continue with optional operation 777, which comprises treating the metal oxo photoresist with a plasma treatment. In an embodiment, the plasma treatment may include a plasma comprising, but not limited to, carbon, hydrogen, and oxygen. Source gasses may include, but are not limited to, O₂, H₂, hydrocarbons, aldehydes, CO₂, CO, H₂O, and H₂O₂.

In an embodiment, the metal oxo photoresist may be exposed and developed. The exposure and the developer chemistry may be substantially similar to the developer chemistry described above with respect to process 440. In a particular embodiment, a 0.05M NaOH developer may be used.

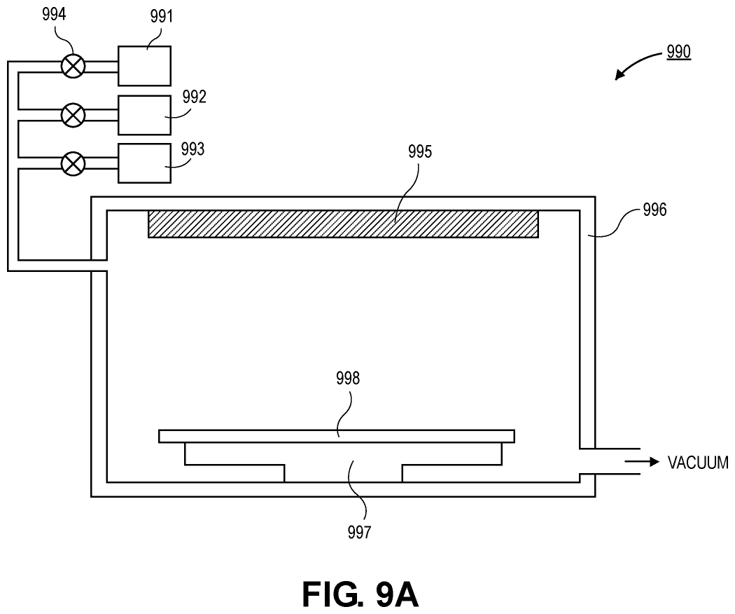

One of the benefits of using a reactive sputtering process is that the material composition of the target (or targets) does not need to match the targeted material composition for the metal oxo photoresist. That is, by changing the flow of gasses (e.g., hydrocarbons, oxygen sources, hydrogen sources, inert gasses, etc.) the composition of the metal oxo photoresist can be changed. In addition to providing flexibility in the material composition generally, a photoresist layer may have a non-uniform composition through a thickness of the photoresist layer. For example, a first layer of the photoresist may have a different composition than a second overlying layer. An embodiment of a process 880 for forming such a metal oxo photoresist is shown in FIG. 8A.

In an embodiment, process 880 may begin with operation 881, which comprises sputtering a first metal oxo layer onto a substrate in a vacuum chamber. In an embodiment, the sputtering process to form the first metal oxo layer may be similar to any of the metal oxo deposition processes described herein.

In an embodiment, process 880 may continue with operation 882, which comprises sputtering a second metal oxo layer onto the first metal oxo layer in the vacuum chamber. The second metal oxo layer may have a different material composition than the first metal oxo layer. An example, of the structure is shown in FIG. 8B. As shown, a first metal oxo layer 802 is over the substrate 801, and a second metal oxo layer 803 is over the first metal oxo layer 802. In a particular embodiment, a thickness of the first metal oxo layer 802 may be smaller than a thickness of the second metal oxo layer 803. For example, the first metal oxo layer 802 may be tuned for adhesion properties, and the second metal oxo layer 802 may be tuned for sensitivity properties. Though, it is to be appreciated that the first metal oxo layer 802 and the second metal oxo layer 803 may be tuned for any desired photoresist property.

In an embodiment, additional layers may also be formed over the second metal oxo layer 803. For example, FIG. 8C shows a plurality of metal oxo layers 802-806. The plurality of layers may form a compositional gradient through a thickness of the photoresist.

Returning now to process 880 may continue with optional operation 883, which comprises treating the multi-layered metal oxo photoresist with a plasma treatment. In an embodiment, the plasma treatment may include a plasma comprising, but not limited to, carbon, hydrogen, and oxygen. Source gasses may include, but are not limited to, O₂, H₂, hydrocarbons, aldehydes, CO₂, CO, H₂O, and H₂O₂.

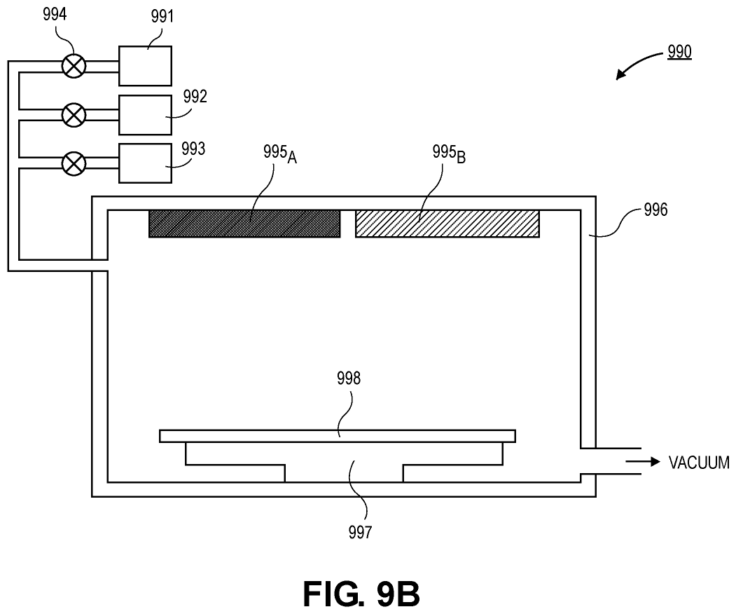

Referring now to FIG. 9A, a cross-sectional illustration of a PVD tool 990 is shown, in accordance with an embodiment. In an embodiment, the PVD tool 990 comprises a vacuum chamber 996. The chamber 996 may be suitable for low pressure operation, such as below approximately 20 mTorr. In an embodiment, the vacuum pressure may be supplied by a vacuum coupled to the chamber 996. In an embodiment, gas sources may be fluidically coupled to the chamber 996. For example, gas sources 991-993 may be fluidically coupled to the chamber 996. The flow of each of the gasses 991-993 may be controlled by valves 994. In an embodiment, gas source 991 may be an inert gas, gas source 992 may be an oxygen containing gas, and gas source 993 may be a carbon containing gas.

In an embodiment, the PVD tool 990 may comprise a pedestal 997. A substrate 998 may be supported by the pedestal 997. The substrate 998 may overhang an edge of the pedestal 997 in some embodiments. Despite having an overhang, the metal oxo layer is not deposited on the backside surface of the substrate 998 since PVD processes are line of sight deposition process. The pedestal may have thermal control (e.g., cooling and/or heating) in order to control a temperature of the substrate 998. In an embodiment, the substrate 998 may be secured to the pedestal 997 with a chucking regime, such as electrostatic chucking or vacuum chucking.

In an embodiment, the PVD tool 990 may further comprise a target 995. The target may be provided opposite from the pedestal 997. In an embodiment, the target 995 may comprise a metal oxo material composition. The metal oxo target 995 may comprise a metal (e.g., Sn, Hf, Zr, etc.), oxygen, and carbon. In a particular embodiment, the metal oxo target comprises Sn, oxygen, and carbon. The target 995 may be formed with various processing techniques. In one embodiment, a metal oxo powder may be cold pressed to form the target. Additional embodiments may include a sintering process of a metal oxo powder. In yet another embodiment, the metal oxo is solution cast and solidified. In an embodiment the solid metal oxo materials may be attached to a metal plate. While particular examples of methods of forming the metal oxo target 995 are shown, it is to be appreciated that the metal oxo target 995 may be formed with any suitable process.

In an embodiment, the target 995 may be used as the cathode for the PVD process. As such, ions from the plasma bombard the target 995 to enable the sputtering process. In an embodiment, the PVD tool 990 may be set up for RF sputtering or pulsed DC sputtering. Such regimes may be necessary since the target 995 is an insulating material. In an embodiment, the target 995 may be actively cooled. That is, a coolant source (not shown) may supply the target 995 with a cooling fluid.

Referring now to FIG. 9B, a cross-sectional illustration of a PVD tool 990 is shown, in accordance with an additional embodiment. The PVD tool 990 in FIG. 9B may be substantially similar to the PVD tool 990 in FIG. 9A, with the exception of the PVD tool 990 being a multi-cathode tool. Particularly, embodiments may include a first target 995_{A} and a second target 995_{B}. While two targets 995 are shown, it is to be appreciated that any number of targets 995 may be included in the PVD tool 990. For example, a target 995_{A} may have a metal oxo composition, and a target 995_{B} may comprise oxygen and/or carbon. In yet another embodiment, the target 995_{A} may comprise a metal, and the target 995_{B} may comprise an oxide material. The use of multiple targets 995 allows for the composition of the layer deposited on the substrate 998 to be modulated. As such, a portion of the deposited layer interfacing with the substrate 998 may be tuned to have a high adhesion, and the remainder of the deposited layer may be tuned for sensitivity.

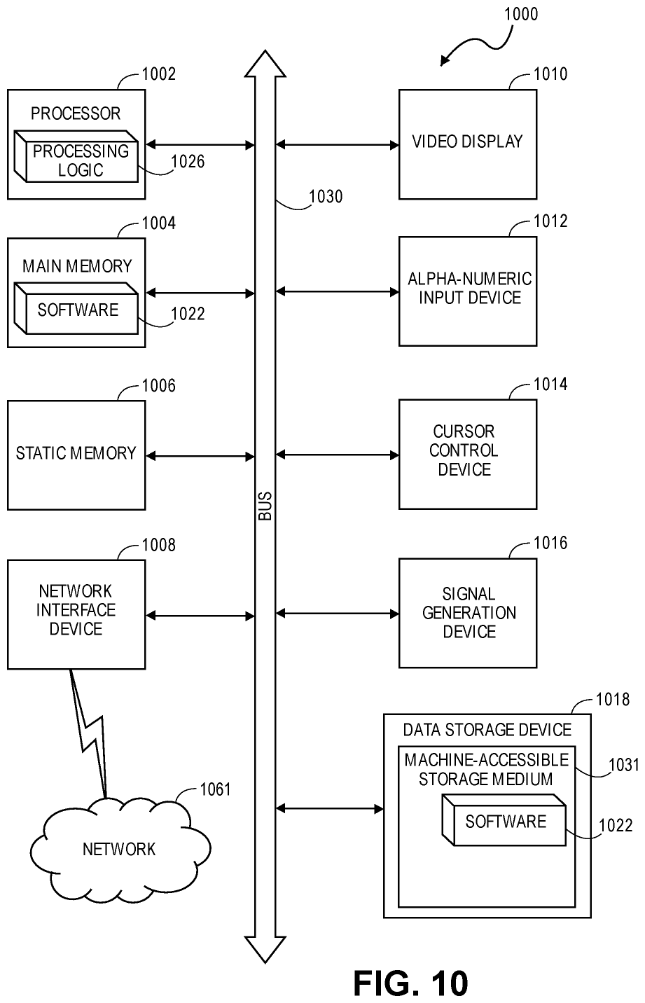

FIG. 10 illustrates a diagrammatic representation of a machine in the exemplary form of a computer system 1000 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 1000 includes a processor 1002, a main memory 1004 (e.g., read-only memory (ROM), flash memory, dynamic random access memory (DRAM) such as synchronous DRAM (SDRAM) or Rambus DRAM (RDRAM), etc.), a static memory 1006 (e.g., flash memory, static random access memory (SRAM), MRAM, etc.), and a secondary memory 1018 (e.g., a data storage device), which communicate with each other via a bus 1030.

Processor 1002 represents one or more general-purpose processing devices such as a microprocessor, central processing unit, or the like. More particularly, the processor 1002 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 1002 may also be one or more special-purpose processing devices such as an application specific integrated circuit (ASIC), a field programmable gate array (FPGA), a digital signal processor (DSP), network processor, or the like. Processor 1002 is configured to execute the processing logic 1026 for performing the operations described herein.

The computer system 1000 may further include a network interface device 1008. The computer system 1000 also may include a video display unit 1010 (e.g., a liquid crystal display (LCD), a light emitting diode display (LED), or a cathode ray tube (CRT)), an alphanumeric input device 1012 (e.g., a keyboard), a cursor control device 1014 (e.g., a mouse), and a signal generation device 1016 (e.g., a speaker).

The secondary memory 1018 may include a machine-accessible storage medium (or more specifically a computer-readable storage medium) 1032 on which is stored one or more sets of instructions (e.g., software 1022) embodying any one or more of the methodologies or functions described herein. The software 1022 may also reside, completely or at least partially, within the main memory 1004 and/or within the processor 1002 during execution thereof by the computer system 1000, the main memory 1004 and the processor 1002 also constituting machine-readable storage media. The software 1022 may further be transmitted or received over a network 1020 via the network interface device 1008.

While the machine-accessible storage medium 1032 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, and optical and magnetic media.

In accordance with an embodiment of the present disclosure, a machine-accessible storage medium has instructions stored thereon which cause a data processing system to perform a method of depositing a metal oxo photoresist on a substrate. The method includes providing a metal oxo target in a vacuum chamber and flowing an inert gas into the vacuum chamber. In an embodiment, the method further comprises striking a plasma in the vacuum chamber and sputtering the metal oxo onto a substrate in the vacuum chamber.

Thus, methods for forming a metal oxo photoresist using PVD processes have been disclosed.

What is claimed is:

1. A method of forming a metal oxo photoresist on a substrate, comprising:
providing a target in a vacuum chamber, wherein the target comprises a metal;
flowing a hydrocarbon gas and an inert gas into the vacuum chamber;
striking a plasma in the vacuum chamber; and
depositing the metal oxo photoresist on the substrate, wherein the metal oxo photoresist comprise metal-carbon bonds and metal-oxygen bonds.

2. The method of claim 1, further comprising:
flowing a supplemental source of oxygen into the vacuum chamber.

3. The method of claim 2, wherein the supplemental source of oxygen comprises one or more of O₂, aldehydes, CO₂, CO, H₂O, N₂O, NO₂, and H₂O₂.

4. The method of claim 1, further comprising:
flowing a supplemental source of hydrogen into the vacuum chamber.

5. The method of claim 4, wherein the supplemental source of hydrogen comprises one or more of H₂, aldehydes, H₂O, and H₂O₂.

6. The method of claim 1, further comprising, flowing a supplemental source of oxygen and a supplemental source of hydrogen into the vacuum chamber.

7. The method of claim 1, further comprising:
treating the metal oxo photoresist with a plasma treatment.

8. The method of claim 7, wherein the plasma treatment comprises a plasma with one or more of C, H, and O.

9. The method of claim 8, wherein a source gas for the plasma treatment comprises one or more of O₂, H₂, hydrocarbons, aldehydes, CO₂, CO, and H₂O.

10. The method of claim 1, wherein a flow of the hydrocarbon gas is approximately 50% or less of a total gas flow into the vacuum chamber.

11. The method of claim 10, wherein the flow of the hydrocarbon gas is approximately 5% of the total gas flow into the vacuum chamber, and wherein a flow of the inert gas is approximately 95% of the total gas flow into the vacuum chamber.

12. A method of forming a metal oxo photoresist on a substrate, comprising:
providing a first target in a vacuum chamber, wherein the first target comprises a metal;
providing a second target in the vacuum chamber, wherein the second target comprises carbon;
flowing a hydrocarbon gas an inert gas into the vacuum chamber;
striking a plasma in the vacuum chamber; and
depositing the metal oxo photoresist on the substrate, wherein the metal oxo photoresist comprise metal-carbon bonds and metal-oxygen bonds.

13. The method of claim 12, wherein the first target further comprises hydrogen.

14. The method of claim 12, wherein the second target further comprises hydrogen.

15. The method of claim 12, wherein the first target further comprises hydrogen and the second target further comprises hydrogen.

16. The method of claim 12, further comprising:
treating the metal oxo photoresist with a plasma treatment process.

17. The method of claim 12, further comprising:
flowing a supplemental source of oxygen and/or hydrogen into the vacuum chamber.

18. A method of depositing a metal oxo photoresist on a substrate, comprising:
sputtering a first metal oxo layer onto the substrate in a vacuum chamber, wherein the first metal oxo layer has a first composition; and
sputtering a second metal oxo layer onto the first metal oxo layer, wherein the second metal oxo layer has a second composition that is different than the first composition.

19. The method of claim 18, wherein the first metal oxo layer is tuned to improve adhesion, and wherein the second metal oxo layer is tuned to improve sensitivity.

20. The method of claim 18, wherein the second layer is thicker than the first layer.
